(19) United States
(12) Patent Application Publication
(10) Pub. No.: US 2026/0358794 A1
(43) Pub. Date: Nov. 12, 2026

(54) SUBSTRATE TREATMENT APPARATUS AND METHOD

(71) Applicant: ACM RESEARCH (SHANGHAI), INC., Shanghai (CN)

(72) Inventors: Wenjin Liu, SHANGHAI (CN); Jin Huang, SHANGHAI (CN); Yinuo Jin, SHANGHAI (CN)

(73) Assignee: ACM RESEARCH (SHANGHAI), INC., Shanghai (CN)

(21) Appl. No.: 19/477,096

(22) PCT Filed: Mar. 20, 2024
(86) PCT No.: PCT/CN2024/082817

§ 371 Date: Oct. 20, 2025

(30) Foreign Application Priority Data
Apr. 19, 2023 (CN) 202310424749.8

(51) Int. Cl. G05B 19/418

(52) U.S. Cl. CPC G05B 19/41875; G05B 2219/37224; G05B 2219/45031

(57) ABSTRACT

The present invention provides a substrate processing method, comprising: measuring characteristic parameter of a liquid film on the surface of a pre-wetted substrate to generate the second characteristic data; acquiring the first characteristic data as comparison data, comparing the second characteristic data with the comparison data to determine whether a pre-wetting result of the substrate is qualified. If an error between the first characteristic data and the second characteristic data is greater than a preset value, determining that the pre-wetting result of the substrate is unqualified; if the error between the first characteristic data and the second characteristic data is less than or equal to the preset value, determining that the pre-wetting result of the substrate is qualified. According to the pre-wetting result, the next treatment process of the substrate is controlled. The present invention can determine the pre-wetting result of the substrate more efficiently and accurately, and avoid the problem that the liquid film on the substrate is uneven after the pre-wetting of the substrate and the voids are formed in the TSV vias of the substrate after electroplating. At the same time, when the pre-wetting result of the same substrate is unsatisfactory repeatedly, a worker can be reminded to check the fault of a machine to ensure safe production.

### FIELD OF THE INVENTION

The present invention relates to the field of semiconductor integrated circuit packaging, and in particular to a substrate processing apparatus and a method.

### BACKGROUND

In recent years, the semiconductor industry has developed by leaps and bounds. The ultra-large-scale integrated circuit (ULSIC) manufacturing industry has been following Moore's Law, and the integration level has doubled every 1.5 years. Advanced packaging technology has become the preferred choice for the future development of semiconductor industry because advanced packaging technology can meet various performance requirements and complex heterogeneous integration requirements. TSV (Through Silicon Via) technology is a high-density packaging technology and is gradually replacing the current mature wire bonding technology. TSV is also known as the fourth generation semiconductor packaging technology. TSV technology creates the vertical communication between chips and between substrates, and fills conductive materials such as copper, tungsten and polysilicon to achieve the vertical electrical interconnection of silicon vias, thereby realizing the interconnection between chips. TSV technology can reduce interconnection length, reduce capacitance/inductance, reduce signal delay, realize high-speed communication between chips, increase broadband and realize miniaturization of device integration.

As the core of the TSV process, the electroplating still has a lot of room for improvement. It is particularly important to improve the filling quality in the TSV vias, and the pre-wetting process before electroplating is the core step to ensure non-porous filling.

In the current TSV pre-wetting process, the nozzle with high water pressure can spray a fan-shaped deionized water to cover the entire substrate. However, due to the influence of the substrate rotation speed and vacuum breaking rate during the process, the thickness of the water film covering the substrate will probably be thin or uneven after pre-wetting, making the moisture in the area with the thin water film easy to completely evaporate. Specifically, when the area with the thicker water film evaporates to the target requirement, the area with the thinner water film has begun to evaporate the moisture within the TSV vias. This will cause some of the bubbles on the top of the TSV vias of the substrate after entering the electroplating chamber and turning over, float at the bottom of the TSV vias and form voids after electroplating. The presence of voids will affect the filling quality in the TSV vias of substrate electroplating. In order to prevent this problem, the current processing method is to slice the substrate after electroplating, and observe the filling quality in the TSV vias by SEM (scanning electron microscope). The detection process is relatively time-consuming and laborious. Therefore, how to determine the pre-wetting result in the TSV vias through an efficient and rapid detection method has become an important problem that those skilled in the art need to solve.

### SUMMARY

In order to more efficiently and accurately determine a substrate pre-wetting result, the present invention provides a substrate processing apparatus and a method.

In the first aspect, the present invention provides a substrate processing method, measuring characteristic parameter of a liquid film on the surface of a pre-wetted substrate to generate the second characteristic data;
acquiring the first characteristic data as comparison data, comparing the second characteristic data with the comparison data to determine whether a pre-wetting result of the substrate is qualified;
if an error between the first characteristic data and the second characteristic data is greater than a preset value, determining that the pre-wetting result of the substrate is unqualified;
if the error between the first characteristic data and the second characteristic data is less than or equal to the preset value, determining that the pre-wetting result of the substrate is qualified;
controlling the next treatment process of the substrate according to the pre-wetting result.

According to an embodiment of the present application, the substrate processing method further includes:
selecting a standard pre-wet substrate, measuring characteristic parameter of the liquid film on the surface of the standard pre-wet substrate, generating the first characteristic data.

According to an embodiment of the present application, the characteristic parameter includes thickness or uniformity of the liquid film.

According to an embodiment of the present application, the step of controlling the next treatment process of the substrate according to the pre-wetting result includes:
when the pre-wetting result of the substrate is detected to be unqualified, the next treatment process of the substrate is a re-wetting process;
when the pre-wetting result of the substrate is detected to be qualified, the next treatment process of the substrate is an electroplating process.

According to an embodiment of the present application, the method further includes:
when the pre-wetting result of the substrate is detected to be unqualified for the first time, issue an alarm and control the substrate to enter the pre-wetting process again;
when the pre-wetting result of the same substrate is unqualified for N times, issue the alarm and remind the hardware check, wherein, N is a positive integer greater than or equal to 2.

In the second aspect, the present invention provides a substrate processing apparatus, comprising:
a detection unit, configured to detect characteristic parameter of a liquid film on the surface of a pre-wetted substrate and generate the second characteristic data, and send the second characteristic data;
a processing unit, configured to pre-store the first characteristic data, and further configured to receive the second characteristic data, and compare the first characteristic data with the second characteristic data to determine whether a pre-wetting result of the substrate is qualified, if an error between the first characteristic data and the second characteristic data is greater than a preset value, determining that the pre-wetting result of the substrate is unqualified; if the error between the first characteristic data and the second characteristic data is less than or equal to the preset value, determining that the pre-wetting result of the substrate is qualified; generate a control instruction according to the determination result, and send the control instruction; wherein, the first characteristic data is the characteristic parameter of the liquid film on the surface of a standard pre-wet substrate;
an execution unit, configured to receive the control instruction sent by the processing unit, control the next treatment process of the substrate according to the control instruction.

According to an embodiment of the present application, the detection unit is further configured to acquire the first characteristic data and send the first characteristic data to the processing unit;
the detection unit acquiring the first characteristic data includes: the detection unit detects the characteristic parameter of the liquid film on the surface of the standard pre-wet substrate selected in advance.

According to an embodiment of the present application, the characteristic parameter includes thickness or uniformity of the liquid film.

According to an embodiment of the present application, the processing unit generating the control instruction according to the determination result includes:
when the pre-wetting result of the substrate is detected to be unqualified, generate the control instruction to re-pre-wet the substrate;
when the pre-wetting result of the substrate is detected to be qualified, generate the control instruction for the substrate to enter the electroplating process.

According to an embodiment of the present application, the processing unit is further configured to count the number of times N of pre-wetting disqualifications of the same substrate.

According to an embodiment of the present application, when N is equal to 1,generate the control instruction for controlling the substrate to re-enter the pre-wetting process and issue an alarm;
when N is a positive integer greater than or equal to 2, generate the control instruction to stop the substrate from continuing the process, issue an alarm and remind the hardware check.

According to an embodiment of the present application, the execution unit is further configured to receive the control instruction sent by the processing unit to stop the pre-wetting process, issue the alarm and remind the hardware check, alert the substrate if the pre-wetting result is unqualified, and issue a reminder that the hardware check is required.

According to an embodiment of the present application, the execution unit comprises a pre-wetting chamber, and the detection unit is disposed in the pre-wetting chamber.

According to an embodiment of the present application, the execution unit comprises a transfer station for transferring the substrate, and the detection unit is provided in the transfer station.

The substrate processing apparatus and the method of the present invention measure characteristic parameter of the liquid film on the surface of the pre-wetted substrate, and then compare with the comparison data after the pre-wetting of the standard substrate, so that the pre-wetting result of the substrate can be determined more efficiently and accurately. Avoid the problem that the liquid film on the substrate is uneven after the substrate is pre-wetted, but it is not detected in time, resulting in the problem that voids are formed in the TSV vias of the substrate after electroplating. At the same time, when the pre-wetting result of the same substrate is unsatisfactory repeatedly, a worker can be reminded to check the fault of the machine to ensure safe production. Other features and advantages of the present invention will be set forth in the following specification. The objects and other advantages of the present invention can be achieved and obtained by the structure pointed out in the specification and the accompanying drawings.

### BRIEF DESCRIPTION OF THE DRAWINGS

In order to more clearly explain the embodiments of the present invention or the technical solutions in the prior art, the drawings that need to be used in the description of the embodiments or the prior art will be briefly introduced below. And it is obvious that the drawings in the following description are some embodiments of the present invention, and for those of ordinary skill in the art, other drawings can be obtained according to these drawings without making creative efforts.

FIG. 1 is a schematic flowchart of a substrate processing method according to an embodiment of the present invention;

FIG. 2 is a schematic structural view of a substrate processing apparatus according to an embodiment of the present invention;

FIG. 3 is a schematic structural view of a detection unit arranged in a pre-wetting chamber according to an embodiment of the present invention;

FIG. 4 is a flowchart of a substrate processing method in which a detection unit is provided in a pre-wetting chamber according to an embodiment of the present invention;

FIG. 5 is a schematic structural view of a detection unit arranged in a transfer station according to an embodiment of the present invention; and

FIG. 6 is a flowchart of a substrate processing method in which a detection unit is provided in a transfer station according to an embodiment of the present invention.

### EMBODIMENTS OF THE INVENTION

In order to make the objects, technical solutions and advantages of the embodiments of the present invention clearer, the technical solutions in the embodiments of the present invention will be clearly and completely described below with reference to the drawings in the embodiments of the present invention. And it is obvious that the described embodiments are part of the embodiments of the present invention, but not all the embodiments. Based on the embodiments in the present invention, all other embodiments obtained by those of ordinary skill in the art without making creative efforts belong to the scope of protection of the present invention.

In the TSV pre-wetting process, the nozzle with high water pressure can spray the fan-shaped deionized water to cover the entire substrate. However, due to the influence of the substrate rotation speed and vacuum breaking rate during the process, the thickness of the water film covering the substrate will probably be thin or thick after pre-wetting, and the moisture in the area with the thin water film is easy to completely evaporated. When the area with the thicker water film evaporates to the target requirement, the area with the thinner water film has begun to evaporate the moisture in the TSV vias. This will cause some of the bubbles on the top of the TSV vias of the substrate after entering the electroplating chamber and turning over, float at the bottom of the TSV vias and form voids. The presence of voids will affect the filling quality in the TSV vias of substrate electroplating. The inventors of the present disclosure propose a substrate processing apparatus and a method for determining the pre-wetting result in the TSV vias, so as to improve the efficiency of detecting the pre-wetting result of the substrate.

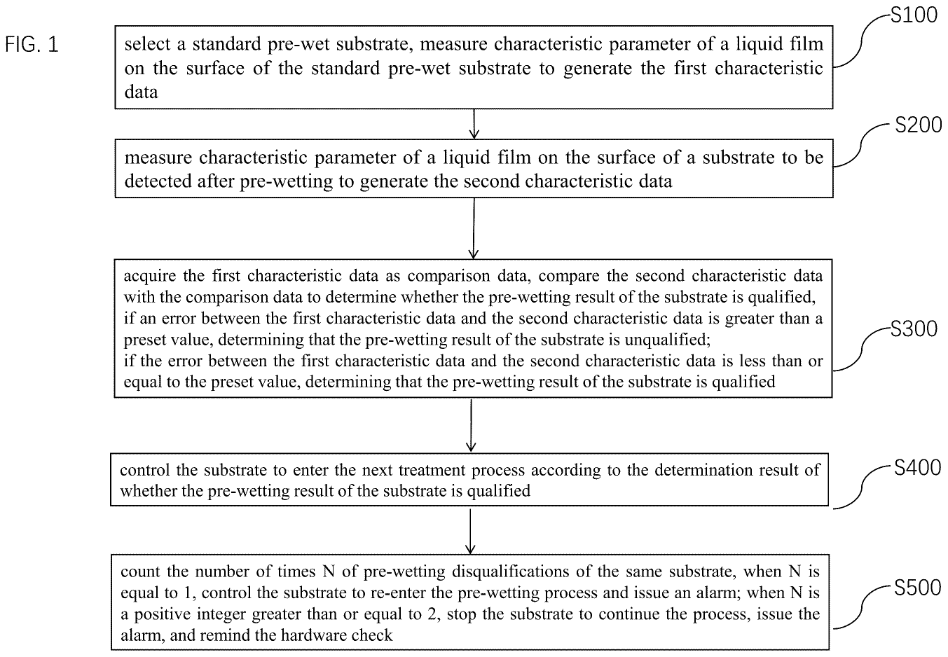

For a substrate processing method according to the present invention, please refer to FIG. 1, FIG. 1 shows a schematic flowchart of the substrate processing method according to an embodiment of the present invention. As shown in FIG. 1, the detection method includes the following steps:
Step S100: select a standard pre-wet substrate, measure characteristic parameter of a liquid film on the surface of the standard pre-wet substrate, generate the first characteristic data;

As the standard pre-wet substrate in the embodiment of the present invention, for example, a substrate having a pre-wet effect satisfying the requirement may be selected as the standard pre-wet substrate from the pre-wetted substrates.
Step S200: measure characteristic parameter of the liquid film on the surface of the substrate to be detected after pre-wetting (hereinafter simply referred to as the substrate) to generate the second characteristic data;
Step S300: acquire the first characteristic data as comparison data, compare the second characteristic data with the comparison data to determine whether the pre-wetting result of the substrate is qualified;

If an error between the first characteristic data and the second characteristic data is greater than a preset value, determining that the pre-wetting result of the substrate is unqualified;

If the error between the first characteristic data and the second characteristic data is less than or equal to the preset value, determining that the pre-wetting result of the substrate is qualified.

Furthermore, the substrate processing method further includes step S400: control the substrate to enter the next treatment process according to the determination result of whether the pre-wetting result of the substrate is qualified.

Specifically, when it is determined that the pre-wetting result of the substrate is unqualified, the next process that the substrate is controlled to enter is a re-wetting process;

When it is determined that the pre-wetting result of the substrate is qualified, the next process that the substrate is controlled to enter is an electroplating process.

Furthermore, the substrate processing method further includes step S500: count the number of times N of pre-wetting disqualifications of the same substrate, when N is equal to 1, control the substrate to re-enter the pre-wetting process and issue an alarm; when N is a positive integer greater than or equal to 2, for example, N is equal to 2 in this embodiment, stop the substrate to continue the process, issue the alarm, and remind the hardware check.

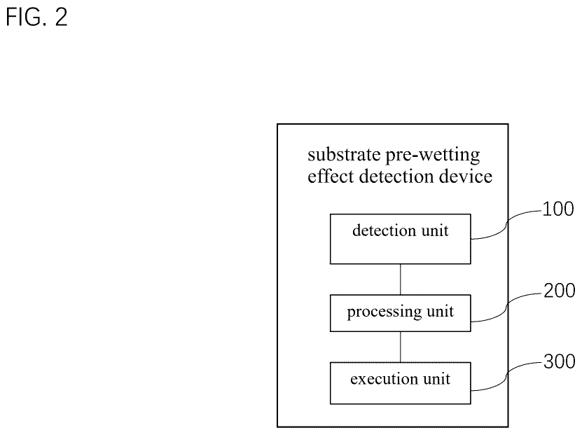

The present invention also provides a substrate processing apparatus for matching the substrate processing method described above. FIG. 2 is a schematic structural view of a substrate processing apparatus according to an embodiment of the present invention. As shown in FIG. 2, the substrate processing apparatus of the present invention comprises a detection unit 100, a processing unit 200 and an execution unit 300.

The detection unit 100 is configured to detect characteristic parameter of the liquid film on the surface of the substrate after the pre-wetting process to generate the second characteristic data, and send the second characteristic data to the processing unit 200. In an embodiment of the present invention, the characteristic parameter includes thickness or uniformity of the liquid film.

Furthermore, the detection unit 100 is further configured to measure characteristic parameter of the liquid film on the surface of the standard pre-wet substrate to generate the first characteristic data, and send the first characteristic data to the processing unit 200. In the embodiment of the present invention, the characteristic parameter includes thickness or uniformity of the liquid film.

The processing unit 200 is configured to pre-store the first characteristic data, the processing unit 200 is further configured to receive the second characteristic data. And compare the first characteristic data with the second characteristic data, determining whether the pre-wetting result of the substrate is qualified. If the error between the first characteristic data and the second characteristic data is greater than the preset value, determining that the pre-wetting result of the substrate is unqualified; If the error between the first characteristic data and the second characteristic data is less than or equal to the preset value, determining that the pre-wetting result of the substrate is qualified. Generate a control instruction based on the determination result, and send the control instruction to the execution unit 300. Wherein, the first characteristic data is the characteristic parameter of the liquid film on the surface of the standard pre-wet substrate. In the present embodiment, the processing unit 200 is a control platform of the apparatus.

The execution unit 300 is configured to receive the control instruction sent by the processing unit, and to control the next process of the substrate according to the control instruction.

Furthermore, the processing unit generating the control instruction according to the determination result includes:

when the pre-wetting result of the substrate is determined to be unqualified, generate the control instruction to re-pre-wet the substrate;

when the pre-wetting result of the substrate is determined to be qualified, generate the control instruction for the substrate to enter the electroplating process.

It is worth noting that in the embodiment of the present invention, the detection unit may be selectively installed in the pre-wetting chamber, may be selectively installed on the transfer station, or may be selectively installed on the manipulator.

Furthermore, the processing unit is further configured to count the number of times N of pre-wetting disqualifications of the same substrate, when N is equal to 1, generate the control instruction for controlling the substrate to re-enter the pre-wetting process and issue the alarm; When N is a positive integer greater than or equal to 2, generate the control instruction to stop the substrate from continuing the process, issue the alarm and remind the hardware check. The execution unit 300 receives the control instruction sent by the processing unit 200, and executes the control instruction.

Hereinafter, the substrate processing method and the apparatus of the present invention will be described in detail with reference to the embodiments.

### Embodiment 1

A substrate processing apparatus, please refer to FIG. 2, the substrate processing apparatus comprises a detection unit 100, a processing unit 200 and an execution unit 300. The detection unit 100 is configured to detect characteristic parameter of a liquid film on the surface of a standard pre-wet substrate selected in advance to generate the first characteristic data, and send the first characteristic data to the processing unit 200, and define the first characteristic data as comparison data; And detect characteristic parameter of the liquid film on the surface of the substrate after the pre-wetting process to generate the second characteristic data, and send the second characteristic data to the processing unit 200. In the embodiment, the characteristic parameter includes a thickness of the liquid film. The processing unit 200 is configured to receive the first characteristic data and the second characteristic data, and compare the first characteristic data and the second characteristic data, determine whether the pre-wetting result of the substrate is qualified, generate a control instruction according to the determination result, and send the control instruction to the execution unit 300. The execution unit 300 receives the control instruction sent by the processing unit 200, and controls the subsequent corresponding process of the substrate according to the control instruction.

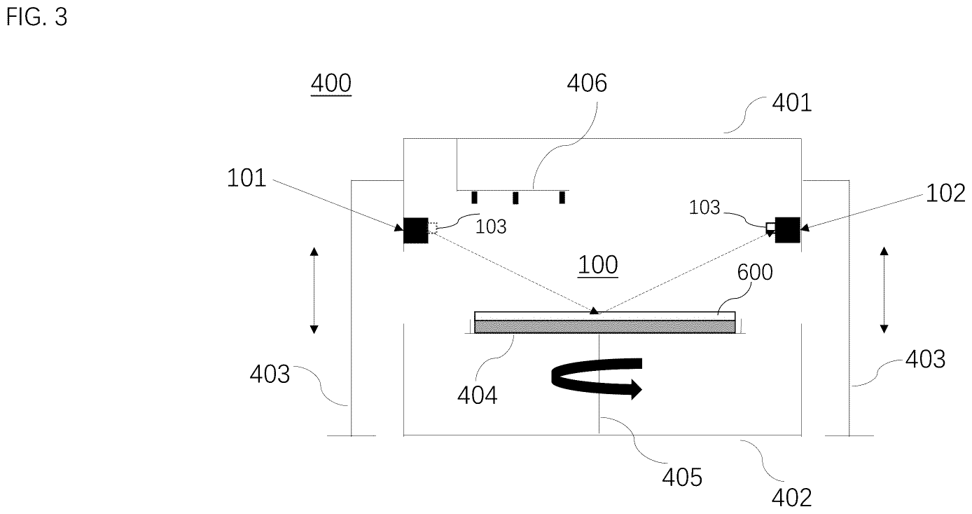

Exemplarily, in the embodiment of the present invention, the detection unit 100 is selectively disposed in the pre-wetting chamber 400. Please refer to FIG. 3, FIG. 3 shows a schematic structural view of a detection unit disposed in the pre-wetting chamber according to the embodiment of the present invention. As shown in FIG. 3, the pre-wetting chamber 400 comprises an upper shell 401 and a lower shell 402, and the upper shell 401 of the pre-wetting chamber is moved up and down in the vertical direction by first driving mechanisms 403, so that the upper shell 401 of the pre-wetting chamber and the lower shell 402 of the pre-wetting chamber come into contact or separate from each other, and the closing or opening of the pre-wetting chamber 400 is achieved. A substrate clamp 404 for holding the substrate 600 horizontally and a second driving mechanism 405 for driving the substrate clamp 404 to drive the substrate 600 to rotate around the plumb line at the center of the substrate 600 as an axis are provided inside the lower shell 402 of the pre-wetting chamber. The upper shell 401 of the pre-wetting chamber is provided with a nozzle 406 for pre-wetting the substrate 600 and the detection unit 100 for detecting the pre-wetting result of the substrate 600. For example, the detection unit 100 in the embodiment of the present invention comprises a detection probe transmitting end 101 and a detection probe receiving end 102, and furthermore, the detection probe transmitting end 101 in the present embodiment is a laser, and the detection probe receiving end 102 is an indium gallium arsenide (InGaAs) detector. In the actual installation process of the detection unit 100, the detection probe transmitting end 101 is provided on the side wall of the upper shell 401 of the pre-wetting chamber, the detection probe receiving end 102 is provided on the side wall of the upper shell 401 of the pre-wetting chamber, and the detection probe transmitting end 101 and the detection probe receiving end 102 are symmetrically arranged about the center of the upper shell 401 of the pre-wetting chamber. When the first driving mechanisms 403 drive the upper shell 401 of the pre-wetting chamber into contact with the lower shell 402 of the pre-wetting chamber, when the pre-wetting chamber 400 is in a sealed state, the detection probe transmitting end 101 is required to be located above the substrate 600 by a predetermined distance, for example, 10 cm.

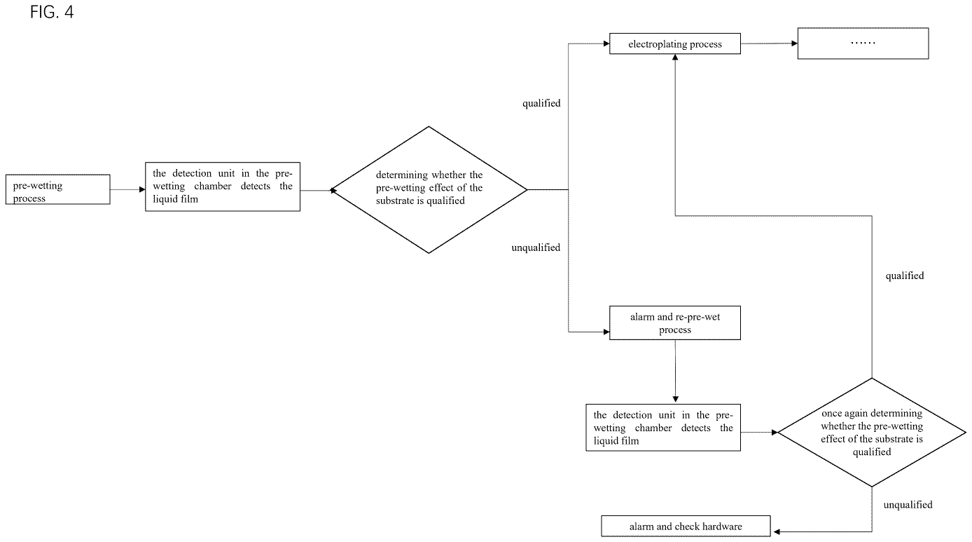

In combination with FIG. 3 and FIG. 4, in the actual process, as shown in FIG. 4, FIG. 4 shows a flowchart of a substrate processing method in which the detection unit is installed in the pre-wetting chamber according to the embodiment of the present invention. When the substrate 600 completes the pre-wetting process, the detection probe transmitting end 101 of the detection unit 100 transmits the laser light. The laser light passes through the surface of the liquid film, and reflects to the detection probe receiving end 102 via the substrate 600. The indium gallium arsenide (InGaAs) detector of the detection probe receiving end 102 receives the laser light, and the detection unit 100 determines the thickness of the liquid film as the second characteristic data according to the data detected by the detection probe receiving end 102.

As is well known, the optical signal detected by the detection unit 100 can be characterized as a numerical value of the thickness of the liquid film by the TDLAS (Tunable Diode Laser Absorption Spectroscopy) liquid film measurement technology. Specifically, the TDLAS liquid film measurement technology can determine the thickness of the water film on the surface of the substrate 600 after the pre-wetting based on the Beer-Lambert law according to the detection of the optical signal on the substrate 600 after the pre-wetting is completed. And the thinner the water film on the surface of the substrate 600, the greater the probability that the water evaporation leads to voids in the TSV vias.

In another embodiment, the detection unit 100 further comprises image collectors 103, and the image collectors 103 may be selectively installed on the detection probe transmitting end 101 or the detection probe receiving end 102. Similarly, the image collectors 103 may be installed according to the actual process environment, in order to collect images of the liquid film on the surface of the substrate after pre-wetting. The installation position and installation method of the present invention are not limited in the embodiment of the present invention for the time being.

At this time, the characteristic parameter is the uniformity of the liquid film, in this embodiment, when the first characteristic data and the second characteristic data are both the uniformity detection of the liquid film, the uniformity of the liquid film of the standard substrate is determined as the first characteristic data, and the uniformity of the liquid film of the substrate to be detected is determined as the second characteristic data. Specifically, by the image detection method, the image collectors are used to collect the image of the liquid film on the surface after normal pre-wetting, and then stored as the first characteristic data. The image is collected on the pre-wetted substrate and referred as the characteristic data, and the first characteristic data and the second characteristic data are compared. The more uniform the water film is, the more consistent the graphic color in the displayed result is. When the color consistency of the image collected by the pre-wetted substrate is lower than the color of the standard graphic, it indicates that the pre-wetting result is unqualified.

After detecting the first characteristic data of the liquid film on the surface of the standard pre-wet substrate, the detection unit 100 first sends the first characteristic data to the processing unit 200 for pre-storage, and then the detection unit 100 detects the substrate to be detected, determines the second characteristic data, and then sends the second characteristic data to the processing unit 200.

The processing unit 200 compares the first characteristic data and the second characteristic data to determine whether the pre-wetting result of the substrate 600 is qualified, and in the process of determining the pre-wetting result of the substrate 600, the processing unit 200 simultaneously counts the number of times of disqualifications of the same substrate 600. The processing unit 200 generates the control instruction in combination with the result of the pre-wetting result of the substrate 600 and the number of times of disqualifications of the pre-wetting result, and sends the control instruction to the execution unit 300.

Specifically, when it is determined that the pre-wetting result of the substrate 600 is unqualified, it indicates that the substrate 600 needs to be re-wetted once, otherwise, once the electroplating is completed, there will be a void phenomenon on the substrate 600, thereby affecting the electroplating quality of the substrate 600. Therefore, it is necessary to generate the first control instruction to re-pre-wet the substrate 600, and at the same time, the first control instruction further includes an instruction to issue an alarm, thereby alerting the worker. The processing unit 200 sends the first control instruction to re-pre-wet the substrate 600 and alert the worker to the execution unit 300.

When it is determined that the pre-wetting result of the substrate 600 is qualified, the first control instruction generated at this time is that the substrate 600 enters the electroplating process, and the processing unit 200 sends the first control instruction for controlling the substrate 600 to enter the electroplating process to the execution unit 300.

The execution unit 300 receives the first control instruction sent by the processing unit 200, and controls the next treatment process of the substrate 600 according to the received first control instruction. The execution unit 300 in the present embodiment comprises, but is not limited to, a mechanical arm, an electroplating chamber, a pre-wetting chamber and an alarm device.

When the first control instruction received by the execution unit 300 is to re-wet the substrate 600, at this time, the execution unit 300 is the mechanical arm for transporting the substrate 600 and the pre-wetting chamber for pre-wetting the substrate 600. The execution unit 300 transports the substrate 600 to the inside of the pre-wetting chamber for re-wetting, and then the detection unit 100 detects the liquid film on the re-wetted substrate 600, and sends the detection result to the processing unit 200. The processing unit 200 re-compares the received second characteristic data with the first characteristic data, determines whether the pre-wetting result of the substrate 600 is qualified, generates the second control instruction based on the determination result, and sends the second control instruction to the execution unit 300.

When it is determined that the pre-wetting result of the re-pre-wetted substrate 600 is qualified, the second control instruction for the substrate 600 to enter the electroplating process is generated. The processing unit 200 sends the second control instruction for controlling the substrate 600 to enter the electroplating process to the execution unit 300. At this time, the execution unit 300 comprises the mechanical arm and the electroplating chamber, and the execution unit 300 transports the substrate 600 into the electroplating chamber to perform an electroplating process. When it is determined that the pre-wetting result of the substrate 600 is unqualified, at this time, the processing unit 200 generates the second control instruction to stop re-wetting the substrate 600, issue the alarm, and remind the worker to perform the hardware check, and sends the second control instruction to the execution unit 300, and at this time, the execution unit 300 comprises the mechanical arm and the alarm device.

### Embodiment 2

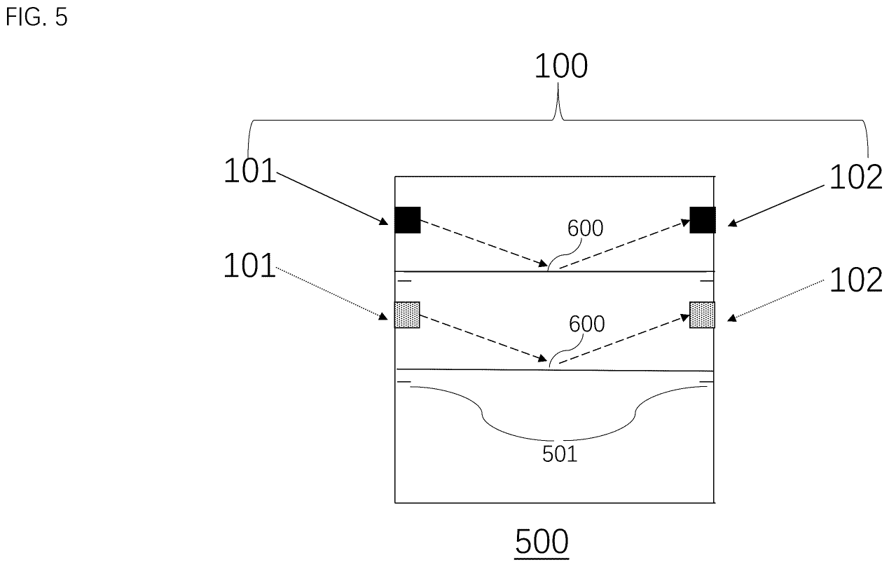

The present embodiment provides a substrate processing apparatus having a structure substantially the same as the structure of the substrate processing apparatus in the first embodiment. In contrast, in the embodiment of the present invention, the detection unit 100 is selectively disposed in the transfer station 500. The transfer station 500 is a device provided between the pre-wetting chamber and the electroplating chamber for relieving the substrate transfer pressure. Please refer to FIG. 5 for details, FIG. 5 shows a schematic structural view in which the detection unit is installed in the transfer station according to the embodiment of the present invention. As shown in FIG. 5, during the installation process, the detection probe transmitting ends 101 are provided on the side wall of the transfer station 500, and the detection probe receiving ends 102 are also provided on the other side wall of the transfer station 500, and the detection probe transmitting ends 101 and the detection probe receiving ends 102 are symmetrically arranged with respect to the central axis of the transfer station 500. The detection probe transmitting ends 101 and the detection probe receiving ends 102 are located above the substrates 600 by a predetermined distance, for example, 10 cm.

It should be understood that the predetermined distance between the substrates 600 and the detection unit 100 is necessary for detection, and therefore, when there are a plurality of substrates 600 in the transfer station 500 and are arranged in parallel in the vertical direction, the distance between each two adjacent substrates 600 is required to be larger than this predetermined distance to ensure that the installation space of the detection unit 100 is sufficient. When there are a plurality of substrate support frames 501 capable of accommodating the plurality of substrates 600 in the transfer station 500, each substrate support frame 501 may be selected to correspond to one detection unit 100 during installation, so as to improve the detection efficiency. As shown in FIG. 5, the plurality of substrate support frames 501 may be selected to correspond to the same detection unit 100, that is, the same detection unit 100 may respectively detect the plurality of substrates in the transfer station 500 one by one, and in this case, the detection unit 100 is required to be movably installed in the transfer station 500 by means of the existing workpieces to save costs. Exemplarily, the workpieces enabling movement include, but are not limited to, guide rails disposed vertically within the transfer station 500.

The rest of the structure of this embodiment is the same as the structure of the first embodiment.

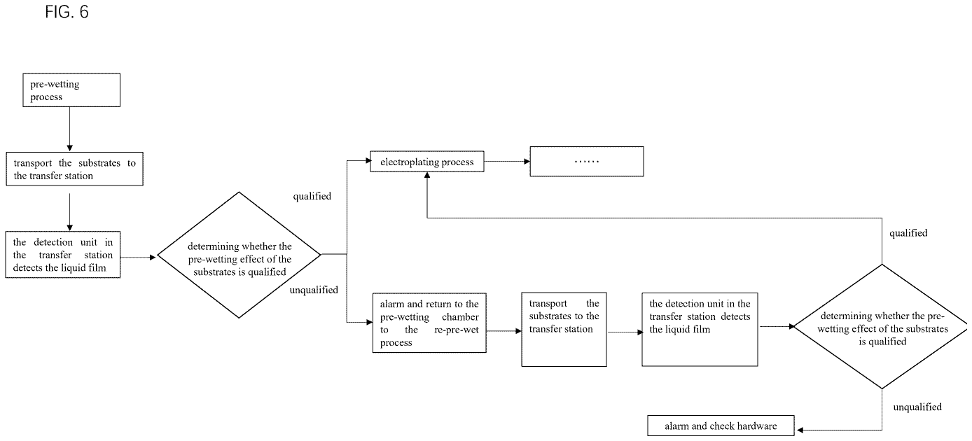

The substrate processing method corresponding to the present embodiment is basically the same as the substrate processing method of the first embodiment. Please refer to FIGS. 5 and 6, FIG. 6 shows a flowchart of the substrate processing method in which the detection unit is installed in the transfer station according to the embodiment of the present invention. The difference is that in the present embodiment, the detection unit 100 needs to transfer the substrates 600 into the transfer station 500 before performing liquid film detection on the substrates 600 after the pre-wetting process is completed, and then performs detection. And when the instruction received by the execution unit 300 is to re-wet the substrates 600, the execution unit 300 first returns the substrates 600 to the pre-wetting chamber and performs the re-wetting processing. And the second characteristic data of the liquid film of the substrate after re-wetting is then sent to the transfer station 500 for re-detection. When the control instruction received by the execution unit 300 is to control the substrate to enter the electroplating process, the execution unit 300 first sends the substrates 600 into the electroplating chamber, and then performs the electroplating process.

Although the present invention has been described in detail with reference to the aforementioned embodiments, those of ordinary skill in the art should understand that the technical solutions described in the aforementioned embodiments may be modified or some technical features may be equivalently replaced. However, these modifications or substitutions do not deviate the essence of the corresponding technical solutions from the spirit and scope of the technical solutions of each embodiment of the present invention.

What is claimed is:

1. A substrate processing method, comprising:
measuring characteristic parameter of a liquid film on the surface of a pre-wetted substrate to generate the second characteristic data;
acquiring the first characteristic data as comparison data, comparing the second characteristic data with the comparison data to determine whether a pre-wetting result of the substrate is qualified;
if an error between the first characteristic data and the second characteristic data is greater than a preset value, determining that the pre-wetting result of the substrate is unqualified;
if the error between the first characteristic data and the second characteristic data is less than or equal to the preset value, determining that the pre-wetting result of the substrate is qualified;
controlling the next treatment process of the substrate according to the pre-wetting result.

2. The substrate processing method according to claim 1, further comprising:
selecting a standard pre-wet substrate, measuring characteristic parameter of the liquid film on the surface of the standard pre-wet substrate, generating the first characteristic data.

3. The substrate processing method according to claim 1, wherein the characteristic parameter includes thickness or uniformity of the liquid film.

4. The substrate processing method according to claim 1, wherein the step of controlling the next treatment process of the substrate according to the pre-wetting result includes:
when the pre-wetting result of the substrate is detected to be unqualified, the next treatment process of the substrate is a re-wetting process;
when the pre-wetting result of the substrate is detected to be qualified, the next treatment process of the substrate is an electroplating process.

5. The substrate processing method according to claim 1, further comprising:
when the pre-wetting result of the substrate is detected to be unqualified for the first time, issuing an alarm and controlling the substrate to enter the pre-wetting process again;
when the pre-wetting result of the same substrate is unqualified for N times, issuing the alarm and reminding the hardware check, wherein, N is a positive integer greater than or equal to 2.

6. A substrate processing apparatus, comprising:
a detection unit, configured to detect characteristic parameter of a liquid film on the surface of a pre-wetted substrate and generate the second characteristic data, and send the second characteristic data;
a processing unit, configured to pre-store the first characteristic data, and further configured to receive the second characteristic data, and compare the first characteristic data with the second characteristic data to determine whether a pre-wetting result of the substrate is qualified, if an error between the first characteristic data and the second characteristic data is greater than a preset value, determining that the pre-wetting result of the substrate is unqualified; if the error between the first characteristic data and the second characteristic data is less than or equal to the preset value, determining that the pre-wetting result of the substrate is qualified; generate a control instruction according to the determination result, and send the control instruction; wherein, the first characteristic data is the characteristic parameter of the liquid film on the surface of a standard pre-wet substrate;
an execution unit, configured to receive the control instruction sent by the processing unit, control the next treatment process of the substrate according to the control instruction.

7. The substrate processing apparatus according to claim 6, wherein:
the detection unit is further configured to acquire the first characteristic data and send the first characteristic data to the processing unit;
the detection unit acquiring the first characteristic data includes:
the detection unit detects characteristic parameter of the liquid film on the surface of the standard pre-wet substrate selected in advance.

8. The substrate processing apparatus according to claim 7, wherein:
the characteristic parameter includes thickness or uniformity of the liquid film.

9. The substrate processing apparatus according to claim 6, wherein:
the processing unit generating the control instruction according to the determination result includes:
when the pre-wetting result of the substrate is detected to be unqualified, generate the control instruction to re-pre-wet the substrate;
when the pre-wetting result of the substrate is detected to be qualified, generate the control instruction for the substrate to enter the electroplating process.

10. The substrate processing apparatus according to claim 9, wherein:
the processing unit is further configured to count the number of times N of pre-wetting disqualifications of the same substrate.

11. The substrate processing apparatus according to claim 10, wherein:
when N is equal to 1, generate the control instruction to control the substrate to re-enter the pre-wetting process and issue an alarm;
when N is a positive integer greater than or equal to 2, generate the control instruction to stop the substrate from continuing the process, issue an alarm and remind the hardware check.

12. The substrate processing apparatus according to claim 11, wherein:
the execution unit is further configured to receive the control instruction sent by the processing unit to stop the pre-wetting process, issue the alarm and remind the hardware check, alert the substrate if the pre-wetting result is unqualified and issue a reminder that the hardware check is required.

13. The substrate processing apparatus according to claim 6, wherein:
the execution unit comprises a pre-wetting chamber, and the detection unit is arranged in the pre-wetting chamber.

14. The substrate processing apparatus according to claim 6, wherein:
the execution unit comprises a transfer station for transferring the substrate, and the detection unit is arranged in the transfer station.
